(19) United States
(12) Patent Application Publication
(10) Pub. No.: US 2014/0034981 A1
(43) Pub. Date: Feb. 6, 2014

(54) LIGHT EMITTING DIODE STRUCTURE

(71) Applicant: Epistar Corporation, Hsinchu (TW)

(72) Inventors: Kuo-Hsin HUNG, Tainan City (TW); Ting-Yu CHEN, Tainan City (TW); Chen OU, Hsinchu (TW)

(73) Assignee: Epistar Corporation, Hsinchu (TW)

(21) Appl. No.: 13/956,746

(22) Filed: Aug. 1, 2013

(30) Foreign Application Priority Data
Aug. 1, 2012 (TW) 101127914

(51) Int. Cl. H01L 33/46

(52) U.S. Cl. CPC H01L 33/46
USPC 257/98

(57) ABSTRACT

A light-emitting diode structure has: a substrate; a light-emitting semiconductor stack on the substrate, wherein the light-emitting semiconductor stack comprises a first semiconductor layer, a second semiconductor layer with electrical polarity different from that of the first semiconductor layer, and a light-emitting layer between the first semiconductor layer and the second semiconductor layer; a first electrode electrically connected to the first semiconductor layer; and a second electrode electrically connected to the second semiconductor layer, wherein the first electrode comprises a contact area and an extension area, and the contact area has a first surface corresponding to the first semiconductor layer and the extension area has a second surface corresponding to the first semiconductor layer, wherein a roughness of the first surface is different from that of the second surface, and the reflectivity of the first surface is smaller than that of the second surface.

### TECHNICAL FIELD

The present application relates to a light-emitting diode structure with high brightness.

### REFERENCE TO RELATED APPLICATION

This application claims the right of priority based on TW application Serial No. 101127914, filed on Aug. 1, 2012, and the content of which is hereby incorporated by reference in its entirety.

### DESCRIPTION OF BACKGROUND ART

The structure and light-emitting theory of a light-emitting diode (LED) are different from that of traditional light sources. Compared to traditional light sources, a light-emitting diode has some advantages, e.g. low power consumption, long lifetime, no warm-up time, and fast response time. Besides, a light-emitting diode is small, shake-resistant, suitable for mass production and easily adopted in a very small unit or an array unit for further applications. Thus, light-emitting diodes (LEDs) are already widely used in many products such as backlights of displays, while light-emitting diodes (LEDs) for lighting application are also growing.

The demand for cost/performance (C/P) value and the brightness per unit area of light-emitting diodes is getting higher due to the wide applications of light-emitting diodes, and to meet the demand, the size of a light-emitting diode chip is enlarged. However, the enlarged light-emitting diode chip results in uneven current distribution. With reference to FIG. 1, a conventional light-emitting diode comprises a first semiconductor layer 22, a second semiconductor layer 26, a first electrode 4 and a second electrode 5. The first electrode 4 comprises a first contact area 4a and an extension area 4b, wherein the first contact area 4a and the second electrode 5 respectively have a metal pad for wire bonding. The extension area 4b is a finger electrode for facilitating current spreading. However, the higher ratio of the area of the extension area 4b to that of the chip, the more the light is hindered or absorbed by the electrode and thus the light extraction efficiency is degraded. Therefore, as shown in FIG. 1B, which shows the cross-sectional diagram of the dotted line AA′ in FIG. 1A, a first surface 43, a second surface 46 and a third surface 53, which are three flat contact surfaces, are formed under the first contact area 4a, the extension area 4b and the second electrode 5 respectively, and the highly reflective layers 41, 45, 51 are formed such that the problem of light hindered or absorbed by the metal pads and the bottom of the finger electrode is alleviated. However, during the follow-up wire bonding process, the metal pads are prone to peeling because of the flat contact surfaces, thereby lowering the quality of wire bonding. The above light-emitting diode is able to combine with a submount to form a lighting device. The lighting device comprises a submount with one circuit; a solder on the submount, by which the above light-emitting diode can be fixed on the submount, and the substrate of the above light-emitting diode is electrically connected to the circuit on the submount; and an electrical connection structure for electrically connecting the pads of the light-emitting diode and the circuit on the submount; wherein the above submount could be a lead frame or a large mounting substrate for facilitating the design of the electrical circuit of the lighting device and increasing the heat dissipation efficiency.

### SUMMARY OF THE DISCLOSURE

A light-emitting diode structure, comprising: a substrate; a light-emitting semiconductor stack on the substrate, wherein the light-emitting semiconductor stack comprises a first semiconductor layer, a second semiconductor layer with electrical polarity different from that of the first semiconductor layer, and a light-emitting layer between the first semiconductor layer and the second semiconductor layer; a first electrode electrically connected to the first semiconductor layer; and a second electrode electrically connected to the second semiconductor layer, wherein the first electrode comprises a contact area and an extension area, and the contact area has a first surface corresponding to the first semiconductor layer and the extension area has a second surface corresponding to the first semiconductor layer, wherein a roughness of the first surface is different from that of the second surface, and the reflectivity of the first surface is smaller than that of the second surface.

### BRIEF DESCRIPTION OF THE DRAWINGS

FIG. 1A schematically shows a conventional light-emitting diode;

FIG. 1B is a cross-sectional diagram showing a conventional light-emitting diode;

FIG. 2A is a cross-sectional diagram showing a light-emitting diode structure in accordance with the first embodiment of the present application;

FIG. 2B is a force diagram of the area for wire bonding;

FIG. 3 is a cross-sectional diagram showing a light-emitting diode structure in accordance with the second embodiment of the present application;

FIG. 4 is a cross-sectional diagram showing a light-emitting diode structure in accordance with the third embodiment of the present application;

FIG. 5 is a cross-sectional diagram showing a light-emitting diode structure in accordance with the fourth embodiment of the present application;

FIG. 6 is a top view of a light-emitting diode structure comprising a plurality of first extension areas in accordance with the present application;

FIGS. 7 and 8 are top views of a light-emitting diode structure in accordance with the fifth embodiment of the present application;

FIG. 9 is a cross-sectional diagram showing a light-emitting diode structure in accordance with the fifth embodiment of the present application;

FIG. 10 is a cross-sectional diagram showing a light-emitting diode structure in accordance with the sixth embodiment of the present application;

FIG. 11 is a cross-sectional diagram showing a light-emitting diode structure in accordance with the seventh embodiment of the present application;

FIG. 12 is a cross-sectional diagram showing a light-emitting diode structure in accordance with the eighth embodiment of the present application;

FIG. 13 is a cross-sectional diagram showing a light-emitting diode structure in accordance with the ninth embodiment of the present application; and

FIG. 14 is a cross-sectional diagram showing a light-emitting diode structure in accordance with the tenth embodiment of the present application.

### DETAILED DESCRIPTION OF PREFERRED EMBODIMENTS

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. Further, the drawings are not precise scale and components may be exaggerated in view of width, height, length, etc. Herein, the similar or identical reference numerals will denote the similar or identical components throughout the drawings.

### First Embodiment

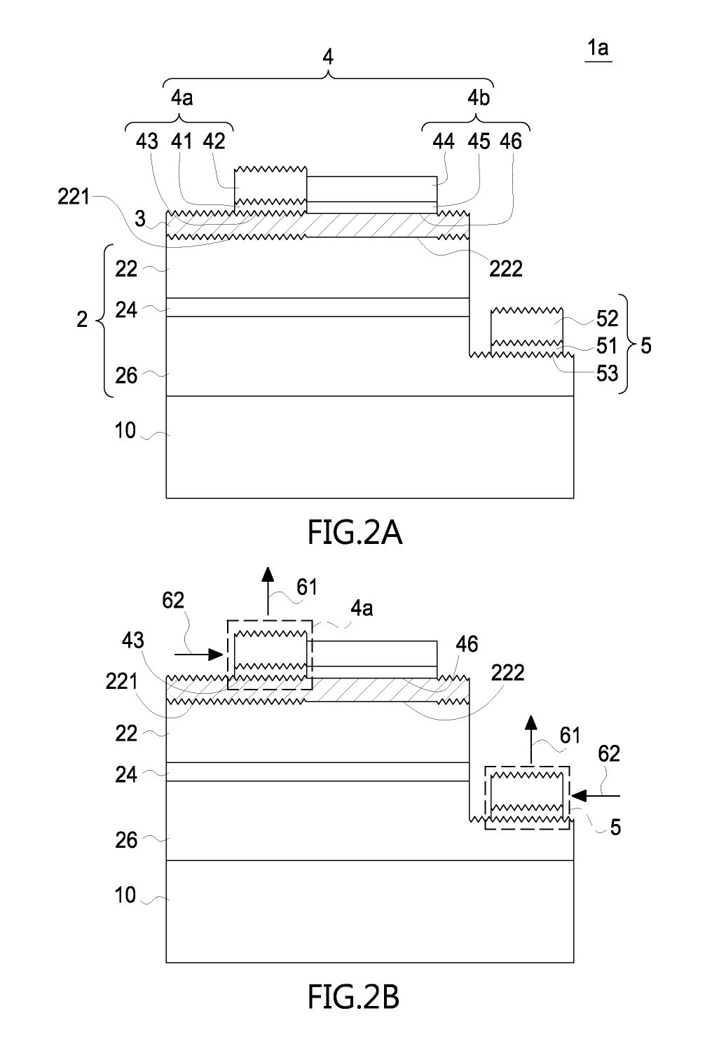

FIG. 2A is a cross-sectional diagram schematically showing a light-emitting diode structure 1a in accordance with the first embodiment of the present application. The light-emitting diode structure 1a comprises a substrate 10. The material of the substrate 10 includes, but is not limited to, insulating material, e.g. silicone, glass, quartz, ceramic, or AlₓN. A light-emitting semiconductor stack 2 on the substrate 10 comprises a first semiconductor layer 22, a light-emitting layer 24, and a second semiconductor layer 26. When the first semiconductor layer 22 is a p-type semiconductor, the second semiconductor layer 26 can be an n-type semiconductor, whose electrical polarity is different from that of the first semiconductor layer 22. On the other hand, when the first semiconductor layer 22 is an n-type semiconductor, the second semiconductor layer 26 can be a p-type semiconductor, whose electrical polarity is different from that of the first semiconductor layer 22. The light-emitting layer 24 between the first semiconductor layer 22 and the second semiconductor layer 26 could be an intrinsic, an n-type or a p-type semiconductor. As an electrical current passes through the light-emitting semiconductor stack 2, the light-emitting layer 24 emits light. When the material of the light-emitting layer 24 is AlGaInP-based, the light-emitting layer 24 can emit light similar to amber color, e.g. red light, orange light, or yellow light. When the material of the light-emitting layer 24 is AlGaInN-based, the light-emitting layer 24 can emit blue light or green light. A transparent conductive layer 3 is formed on the first semiconductor layer 22. The material of the transparent conductive layer 3 includes, but is not limited to, ITO, InO, SnO, CTO, ATO, ZnO, GaP or combinations thereof.

A first electrode 4 is formed on the transparent conductive layer 3 and ohmically contacts the transparent conductive layer 3. The first electrode 4 is electrically connected to the first semiconductor layer 22 through the transparent conductive layer 3. When a current is injected from the first electrode 4, the uniformity of the current distribution is increased by the transparent conductive layer 3, thereby the current is prevented from concentrating in part of the first semiconductor layer 22. A second electrode 5 is formed on the second semiconductor layer 26 and ohmically contacts the second semiconductor layer 26.

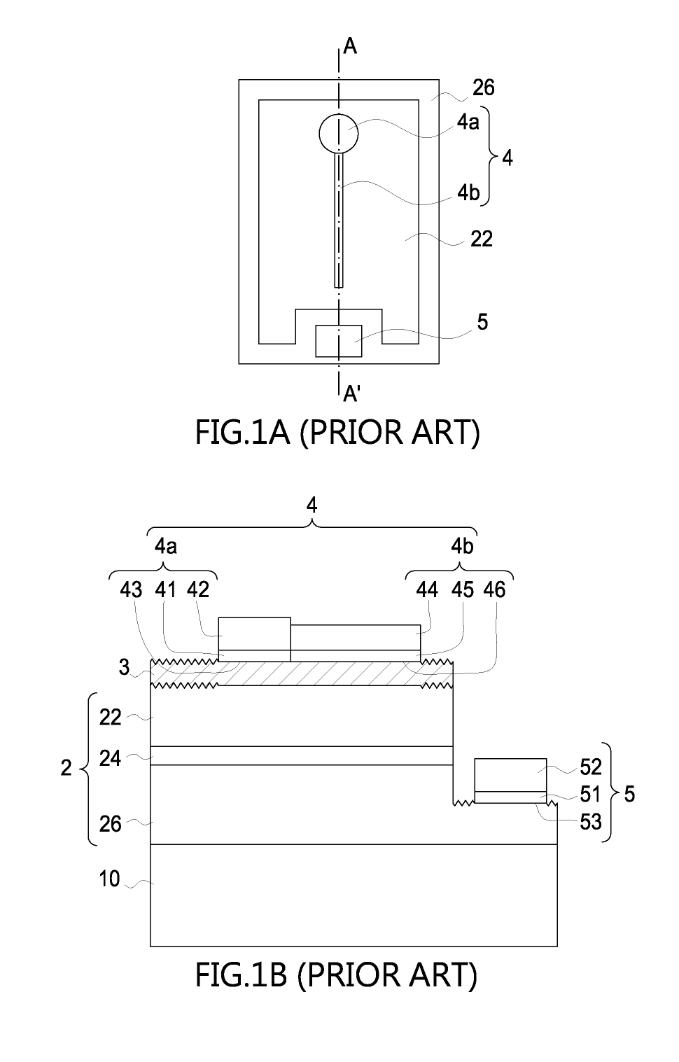

The first electrode 4 comprises a first contact area 4a and one or a plurality of first extension areas 4b, wherein the shape of the first extension area 4b is different from that of the first contact area 4a. For example, with reference to FIG. 1A, the first electrode 4 comprises a round first contact area 4a and a strip-shaped first extension area 4b, and with reference to FIG. 6, the first electrode 4 comprises a round first contact area 4a and two L-shaped first extension area 4b. The first contact area 4a comprises a first solder pad 42, a highly reflective layer 41 and a first surface 43 ohmically contacting the transparent conductive layer 3. The first extension area 4b comprises one or a plurality of first finger electrodes 44, a highly reflective layer 45 and a second surface 46 ohmically contacting the transparent conductive layer 3. The first solder pad 42 of the first contact area 4a is for wire bonding so as to steer the external current into the light-emitting semiconductor stack 2. The first solder pad 42 includes, but is not limited to, a single-layer or a multi-layer metallic structure made of Ni, Ti, Al, Au, or combinations thereof. The highly reflective layer 41 is under the first solder pad 42 and ohmically contacts the transparent conductive layer 3. The material of the highly reflective layer 41 includes, but is not limited to, metals which have good electrical conductivity and have reflectivity larger than 70% in the visible spectrum. The highly reflective layer 41 includes, but is not limited to, a single-layer or a multi-layer metallic structure made of Al, Au, Pt, Ag, Rh, or combinations thereof. The first finger electrode 44 of the first extension area 4b for spreading the current into the transparent conductive layer 3 includes, but is not limited to, a single-layer or a multi-layer metallic structure made of Ni, Ti, Al, Au or combinations thereof. The highly reflective layer 45 is under the first finger electrode 44 and ohmically contacts the transparent conductive layer 3. The material of the highly reflective layer 45 includes, but is not limited to, metals which have good electrical conductivity and have reflectivity larger than 70% in the visible spectrum. The highly reflective layer 45 includes, but is not limited to, a single-layer or a multi-layer metallic structure made of Al, Au, Pt, Ag, Rh, or combinations thereof.

Compared to the second surface 46, the first surface 43 of the first electrode 4, which ohmically contacts the transparent conductive layer 3, has a larger roughness. The roughness (Ra) of the first surface 43 is at least larger than 100 nm, and more specifically, the roughness (Ra) of the second surface 46 is at least smaller than 60 nm. In the present embodiment, the roughness (Ra) of the first surface 43 is 137 nm, and the roughness (Ra) of the second surface 46 is 28.1 nm. The first contact area 4a is provided for wire bonding, and the adhesion of the first contact area 4a must be higher than that of the first extension area 4b so as to avoid a peeling problem during the wire bonding process. FIG. 2B is a force diagram of the first contact area 4a and the second electrode 5. Compared to a flat contact surface, the contact area of a rough contact surface is larger, and thus the first surface 43 of the first contact area 4a, which contacts the transparent conductive layer 3, is capable of making the first contact area 4a withstand more tension force 61 perpendicular to the first surface 43 during the packaging process of the light-emitting diode structure 1a. Besides, a rough contact surface has a concavo-convex structure that is uneven, and thus the first contact area 4a is capable of withstanding more shear force 62 parallel to the first surface 43. The second surface 46 of the first extension area 4b, which contacts the transparent conductive layer 3, is a flat contact surface having a roughness (Ra) smaller than 60 nm for reflecting the light emitted from the light-emitting layer 24, thereby improving the light extraction efficiency. A method of forming the second surface 46 comprises the steps of: patterning a rough upper surface 221 of the first semiconductor layer 22 by chemical etching or dry etching to form a flat region 222, and more preferably, patterning the rough upper surface 221 by dry etching; and forming the transparent conductive layer 3 and the first electrode 4 on the upper surface 221, wherein the second surface 46 corresponds to the flat region 222 so as to render the roughness (Ra) of the second surface 46 smaller than that of the first surface 43.

The reflectivity of the first surface 43 is smaller than that of the second surface 46 since the first surface 43 of the first contact area 4a is a rough surface. More specifically, the reflectivity of the first surface 43 is at least 30% smaller than that of the second surface 46. Accordingly, in other embodiments, the first contact area 4a could be without the highly reflective layer 41.

The second electrode 5 comprises a second solder pad 52, a highly reflective layer 51 and a third surface 53 ohmically contacting the second semiconductor layer 26, wherein the second solder pad 52 is for wire bonding so as to steer the external current into the light-emitting semiconductor stack 2. The second solder pad 52 includes, but is not limited to, a single-layer or a multi-layer metallic structure made of Ni, Ti, Al, Au, or combinations thereof. The highly reflective layer 51 is under the second solder pad 52 and ohmically contacts the second semiconductor layer 26. The material of the highly reflective layer 51 includes, but is not limited to, metals which have good electrical conductivity and have reflectivity larger than 70% in the visible spectrum. The highly reflective layer 51 includes, but is not limited to, a single-layer or a multi-layer metallic structure made of Al, Au, Pt, Ag, Rh, or combinations thereof. The roughness of the third surface 53 is approximate to that of the first surface 43. More specifically, the roughness of the third surface 53 is larger than 100 nm so as to make the second electrode 5 withstand more tension force 61 perpendicular to the third surface 53 during the packaging process of the light-emitting diode structure 1a, as shown in FIG. 2B. Furthermore, the second electrode 5 is capable of withstanding more shear force 62 parallel to the third surface 53 since a rough contact surface has a concavo-convex structure that is uneven.

### Second Embodiment

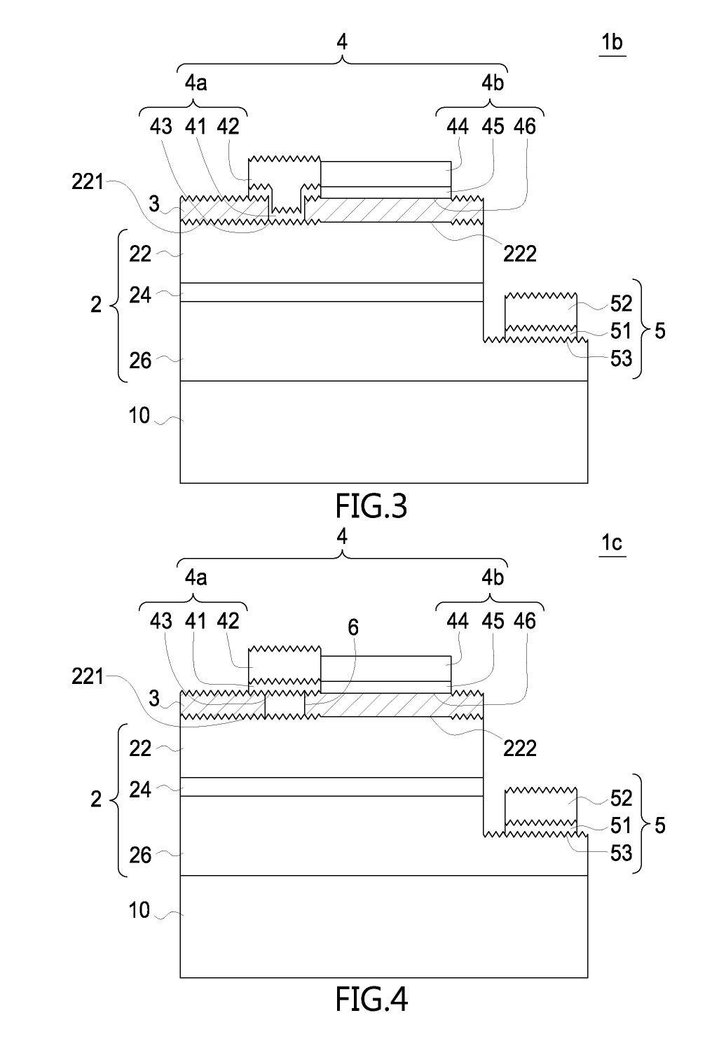

FIG. 3 is a cross-sectional diagram schematically showing a light-emitting diode structure 1b in accordance with the second embodiment of the present application. The difference between the second embodiment and the first embodiment is that the first electrode 4 comprises a first contact area 4a directly contacting the first semiconductor layer 22, that is, most of the highly reflective layer 41 of the first contact area 4a directly contacts the first semiconductor layer 22, and only a small portion of the highly reflective layer 41 ohmically contacts the transparent conductive layer 3. The contact surface between the highly reflective layer 41 and the first semiconductor layer 22 that are directly contacted forms a non-ohmic contact, and the contact surface has high resistance to block the current from flowing through so the luminous flux of the area under the first contact area 4a is lowered and the light absorbed by the first surface 43 is reduced. The current therefore concentrates on all the area other than the area under the first contact area 4a. Thus, the light extraction efficiency of the light-emitting diode structure 1b is improved.

### Third Embodiment

FIG. 4 is a cross-sectional diagram showing a light-emitting diode structure 1c in accordance with the third embodiment of the present application. The difference between the third embodiment and the second embodiment is that an insulating layer 6 is formed between the first contact area 4a and the first semiconductor layer 22. The insulating layer 6 is a current-blocking structure having high resistance to bloc current from flowing through the first surface 43 so the luminous flux of the area under the first contact area 4a is lowered and the light absorbed by the first surface 43 is reduced. The material of the insulating layer 6 includes, but is not limited to, organic materials, e.g. Su8, BCB, PFCB, Epoxy, Acrylic Resin, COC, PMMA, PET, PC, polyetherimide, fluorocarbon polymer; inorganic materials, e.g. silicone, glass; dielectric materials, e.g. Al₂O₃, SiNₓ, SiO₂, TiO₂, or combinations thereof.

### Fourth Embodiment

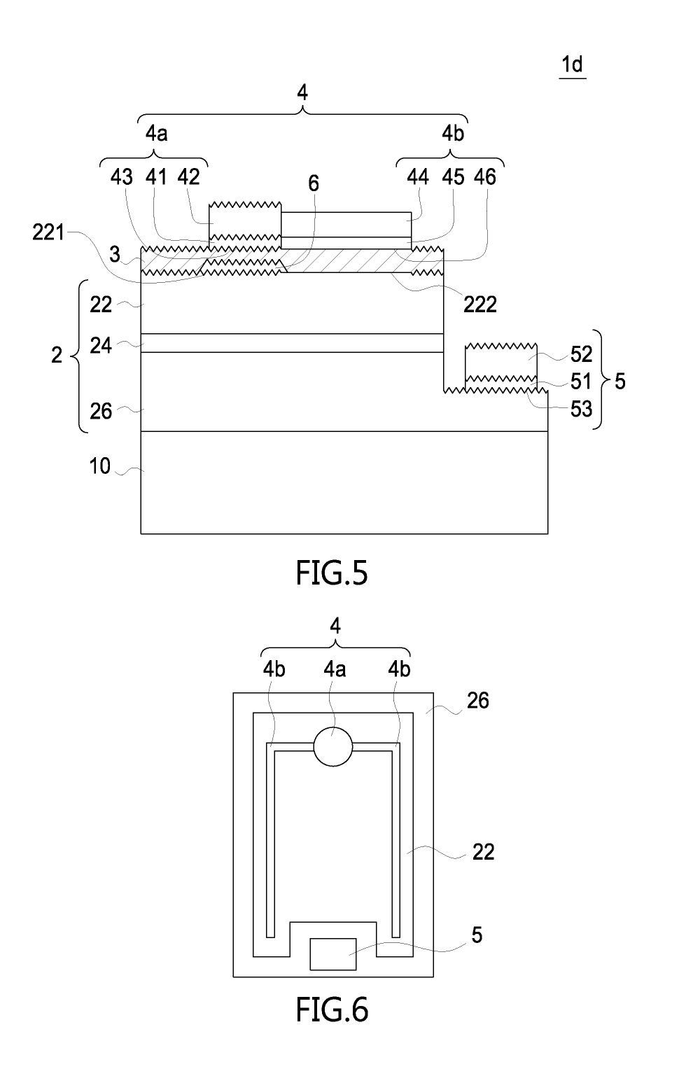

FIG. 5 is a cross-sectional diagram showing a light-emitting diode structure 1d in accordance with the fourth embodiment of the present application. The difference between the fourth embodiment and the first embodiment is that an insulating layer 6 is formed between the transparent conductive layer 3 and the first semiconductor layer 22 and the insulating layer 6 is under the first contact area 4a to block current from flowing through the first surface 43 so the luminous flux of the area under the first contact area 4a is lowered and the light absorbed by the first surface 43 is reduced. The material of the insulating layer 6 includes, but is not limited to, organic materials, e.g. Su8, BCB, PFCB, Epoxy, Acrylic Resin, COC, PMMA, PET, PC, polyetherimide, fluorocarbon polymer; inorganic materials, e.g. silicone, glass; dielectric materials, e.g. Al₂O₃, SiNₓ, SiO₂, TiO₂, or combinations thereof.

### Fifth Embodiment

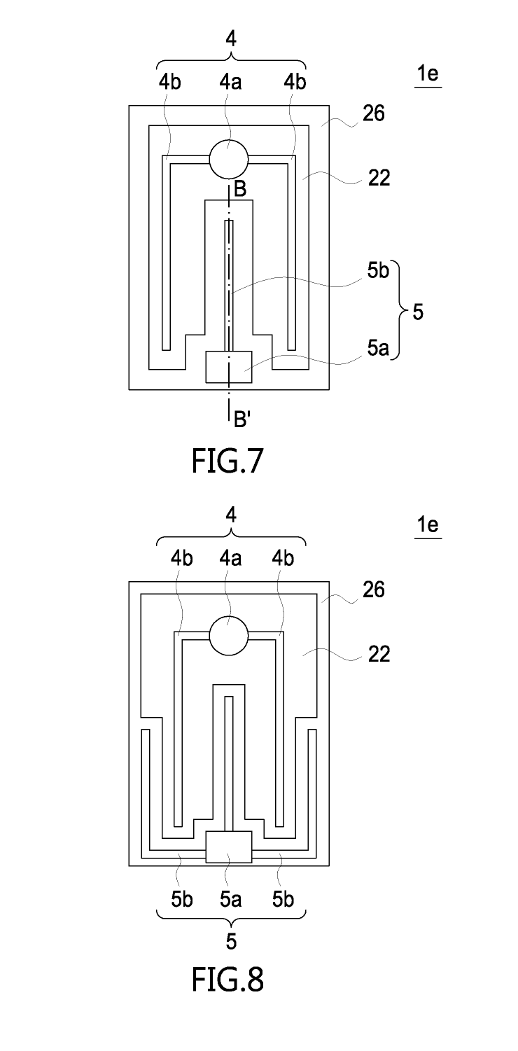

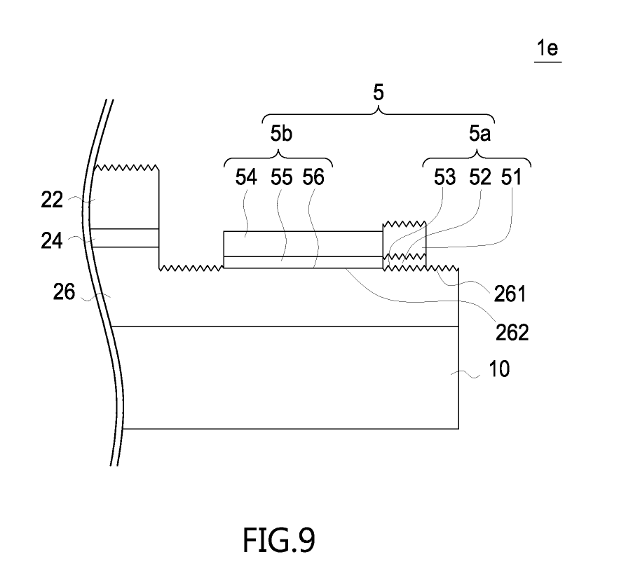

FIGS. 7 and 8 schematically show a light-emitting diode structure 1e in accordance with the fifth embodiment of the present application. The difference between the fifth embodiment and the first to the fourth embodiments is that the second electrode 5 comprises a second contact area 5a and one or a plurality of second extension areas 5b, wherein the shape of the second extension area 5b is different from that of the second contact area 5a. For example, with reference to FIG. 7, the second electrode 5 comprises a quadrate second contact area 5a and a strip-shaped second extension area 5b, and with reference to FIG. 8, the second electrode 5 comprises a quadrate second contact area 5a and two strip-shaped and L-shaped second extension areas 5b. More specifically, the shape of the second contact area 5a is square or rectangular, and more preferably, the shape of the second contact area 5a is square. FIG. 9 shows the cross-sectional diagram of the dotted line BB′ in FIG. 7. The second extension area 5b comprises one or a plurality of second finger electrodes 54, a highly reflective layer 55 and a fourth surface 56 ohmically contacting the second semiconductor layer 26, wherein the roughness (Ra) of the fourth surface 56 is smaller than that of the third surface 53. A method of forming the fourth surface 56 comprises the steps of: patterning a upper surface 261 of the second semiconductor layer 26 by chemical etching or dry etching to form a flat region 262, and more preferably, patterning the upper surface 261 by dry etching; and forming the second electrode 5 on the upper surface 261, wherein the fourth surface 56 is formed on the flat region 262 so as to render the roughness (Ra) of the fourth surface 56 smaller than that of the third surface 53. The second finger electrode 54 for spreading the current into the second semiconductor layer 26 includes, but is not limited to, a single-layer or a multi-layer metallic structure made of Ni, Ti, Al, Au or combinations thereof. The highly reflective layer 5 is under the second finger electrode 54 and ohmically contacts the second semiconductor layer 26. The material of the highly reflective layer 55 includes, but is not limited to, metals which have good electrical conductivity and have reflectivity larger than 70% in the visible spectrum. The highly reflective layer 55 includes, but is not limited to, a single-layer or a multi-layer metallic structure made of Al, Au, Pt, Ag, Rh, or combinations thereof so as to prevent the second extension area 5b from absorbing the light, thereby improving the light extraction efficiency of the light-emitting diode structure 1e.

### Sixth Embodiment

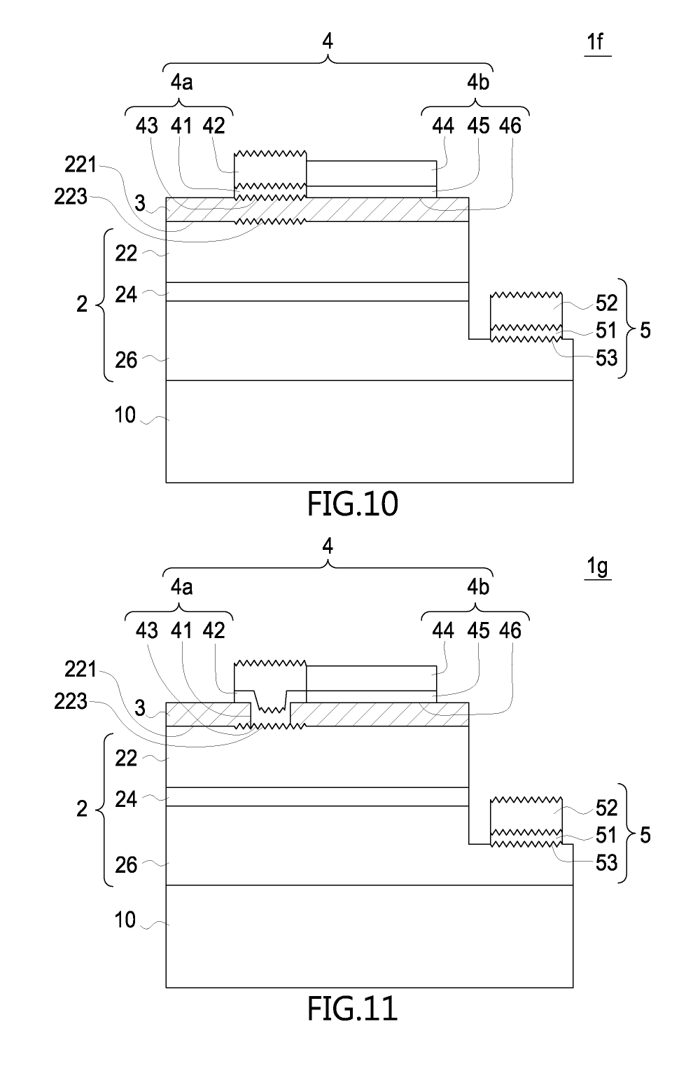

FIG. 10 is a cross-sectional diagram showing a light-emitting diode structure 1f in accordance with the sixth embodiment of the present application. The difference between the sixth embodiment and the first embodiment is that the upper surface 221 of the first semiconductor layer 22 is a flat surface, and a rough region 223 is formed by patterning a portion of the upper surface 221 by chemical etching or dry etching, and more preferably, by patterning a portion of the upper surface 221 by dry etching. The roughness (Ra) of the first surface 43 on the rough region 223 is larger than 100 nm, and the roughness (Ra) of the second surface 46 on the flat upper surface 221 is smaller than 60 nm.

### Seventh Embodiment

FIG. 11 is a cross-sectional diagram showing a light-emitting diode structure 1g in accordance with the seventh embodiment of the present application. The difference between the seventh embodiment and the second embodiment is that the upper surface 221 of the first semiconductor layer 22 is a flat surface, and a rough region 223 is formed by patterning a portion of the upper surface 221 by chemical etching or dry etching, and more preferably, by patterning a portion of the upper surface 221 by dry etching. The roughness (Ra) of the first surface 43 on the rough region 223 is larger than 100 nm, and the roughness (Ra) of the second surface 46 on the flat upper surface 221 is smaller than 60 nm.

### Eighth Embodiment

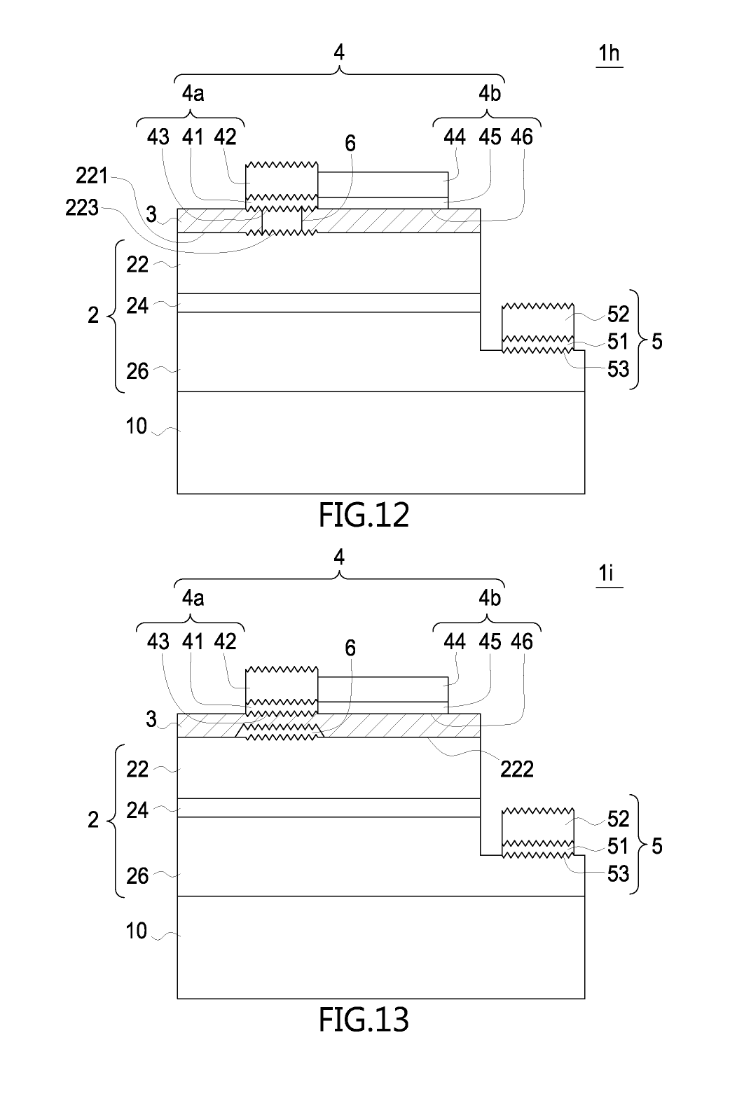

FIG. 12 is a cross-sectional diagram showing a light-emitting diode structure 1h in accordance with the eighth embodiment of the present application. The difference between the eighth embodiment and the third embodiment is that the upper surface 221 of the first semiconductor layer 22 is a flat surface, and a rough region 223 is formed by patterning a portion of the upper surface 221 by chemical etching or dry etching, and more preferably, by patterning a portion of the upper surface 221 by dry etching. The roughness (Ra) of the first surface 43 on the rough region 223 is larger than 100 nm, and the roughness (Ra) of the second surface 46 on the flat upper surface 221 is smaller than 60 nm.

### Ninth Embodiment

FIG. 13 is a cross-sectional diagram showing a light-emitting diode structure 1i in accordance with the ninth embodiment of the present application. The difference between the ninth embodiment and the fourth embodiment is that the upper surface 221 of the first semiconductor layer 22 is a flat surface, and a rough region 223 is formed by patterning a portion of the upper surface 221 by chemical etching or dry etching, and more preferably, by patterning a portion of the upper surface 221 by dry etching. The roughness (Ra) of the first surface 43 on the rough region 223 is larger than 100 nm, and the roughness (Ra) of the second surface 46 on the flat upper surface 221 is smaller than 60 nm.

### Tenth Embodiment

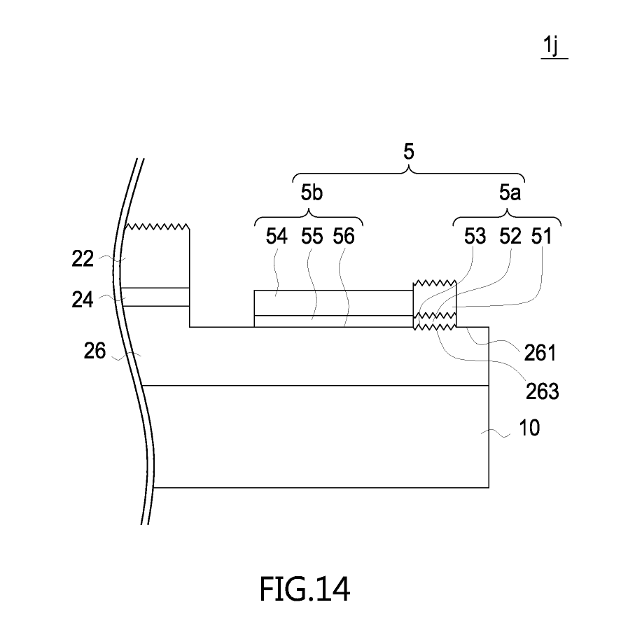

FIG. 14 is a cross-sectional diagram showing a light-emitting diode structure 1j in accordance with the tenth embodiment of the present application. The difference between the tenth embodiment and the fifth embodiment is that the upper surface 261 of the second semiconductor layer 26 is a flat surface, and a rough region 263 is formed by patterning a portion of the upper surface 261 by chemical etching or dry etching, and more preferably, by patterning a portion of the upper surface 261 by dry etching. The roughness (Ra) of the third surface 53 on the rough region 263 is larger than 100 nm, and the roughness (Ra) of the fourth surface 56 on the flat upper surface 261 is smaller than 60 nm.

The foregoing description of preferred and other embodiments in the present disclosure is not intended to limit or restrict the scope or applicability of the inventive concepts conceived by the Applicant. In exchange for disclosing the inventive concepts contained herein, the Applicant desires all patent rights afforded by the appended claims. Therefore, it is intended that the appended claims include all modifications and alterations to the full extent that they come within the scope of the following claims or the equivalents thereof.

What is claimed is:

1. A light-emitting diode structure, comprising:
a substrate;
a light-emitting semiconductor stack on the substrate, wherein the light-emitting semiconductor stack comprises a first semiconductor layer, a second semiconductor layer with electrical polarity different from that of the first semiconductor layer, and a light-emitting layer between the first semiconductor layer and the second semiconductor layer;
a first electrode electrically connected to the first semiconductor layer; and
a second electrode electrically connected to the second semiconductor layer,
wherein the first electrode comprises a contact area and an extension area, and
the contact area has a first surface corresponding to the first semiconductor layer and the extension area has a second surface corresponding to the first semiconductor layer, wherein a roughness of the first surface is different from that of the second surface, and the reflectivity of the first surface is smaller than that of the second surface.

2. The light-emitting diode structure according to claim 1, further comprising a transparent conductive layer between the first electrode and the first semiconductor layer.

3. The light-emitting diode structure according to claim 1, wherein the contact area comprises a metal pad.

4. The light-emitting diode structure according to claim 1, wherein the extension area comprises one or a plurality of finger electrodes.

5. The light-emitting diode structure according to claim 1, wherein a pattern of the contact area is different from that of the extension area.

6. The light-emitting diode structure according to claim 1, wherein the roughness of the first surface is larger than that of the second surface.

7. The light-emitting diode structure according to claim 1, wherein the first surface comprises an uneven concavo-convex structure and the second surface comprises a flat surface.

8. The light-emitting diode structure according to claim 1, wherein the roughness of the first surface is larger than 100 nm.

9. The light-emitting diode structure according to claim 1, wherein the roughness of the second surface is smaller than 60 nm.

10. The light-emitting diode structure according to claim 1, wherein the second electrode comprises a third surface corresponding to the second semiconductor layer, and a roughness of the third surface is larger than 100 nm.

11. The light-emitting diode structure according to claim 2, wherein the first
